(19) United States
(12) Patent Application Publication
(10) Pub. No.: US 2014/0340174 A1
(43) Pub. Date: Nov. 20, 2014

(54) ACTIVE FILTER WITH DUAL RESPONSE

(71) Applicant: THOMSON LICENSING, Issy de Moulineaux (FR)

(72) Inventors: Raafat Lababidi, Brest (FR); Julien Lintignat, Limoges (FR); Dominique Lo Hine Tong, Rennes (FR); Ali Louzir, Rennes (FR); Bruno Barelaud, Isle (FR); Bernard Jarry, Chaleix (FR)

(73) Assignee: Thomson Licensing, Issy de Moulineaux (FR)

(21) Appl. No.: 14/362,757

(22) PCT Filed: Dec. 6, 2012
(86) PCT No.: PCT/EP2012/074670

§ 371 Date: Jun. 4, 2014

(30) Foreign Application Priority Data
Dec. 13, 2011 (FR) 1161524
Dec. 6, 2012 (EP) PCT/EP2012/074670

(51) Int. Cl. H01P 1/20

(52) U.S. Cl. CPC H03H 11/10; H03H 2011/0488
USPC 333/202

(57) ABSTRACT

Based on an active low-pass filter structure comprising a main conductor line between an input port and an output port, consisting of an input conductor section, an output conductor section, and an inductance network in series between the input and output sections, the inductance network being coupled to the LC resonators, an LC resonator connected to each junction point between two network inductances, and at least one negative resistance in series with one of the resonators, a dual response filter is formed by providing an auxiliary conductor line, wherein an input end of the filter is connected to an electrical ground, forming a resonator with its own resonant frequency less than the cut-off frequency f_{c} of the low-pass filter, the auxiliary line extending from this end along and away from the main line. The resonator forms by coupling a rejection filter around the resonant frequency within the bandwidth in the low-pass filter.

### FIELD OF THE INVENTION

The invention relates to an active filter with selective dual response allowing the rejection of a parasitic frequency band outside the bandwidth of a low pass filter, and the rejection of a parasitic band within the bandwidth of a low pass filter. It is part of the SRAMM project for developing multi-standard multi-mode adaptive receiving systems.

The integration of different communication systems in a single communicating object, typically a mobile terminal, involves problems of coexistence due in particular to the proximity of the operating frequency bands allocated to each system. In particular, with the digital era, the communication systems known as 4^{th} generation, including the “mobile” LTE standard are allocated new frequency bands made available by the switch-off of analogue television. Thus, in the United States, for example, the LTE standard can use a new frequency band around 700 MHz, within the frequency band 470-790 MHz used by digital television (DVB-H/T). Cellular phones (GSM and developments, UMTS, etc.) use frequency bands of 890 to 915 MHz and 925 to 960 MHz respectively in transmission and reception. Hereinafter, we note that in the literature on these subjects the frequency bands are often distinguished not by the corresponding frequency range but by an associated system or standard of communication. The same applies for the transmitted or received signals according to these standards. This patent application uses the same simplification of language, including mentioning, for example, standard, GSM band or signals, DVB-H/T, LTE, etc.

Concerning the invention, there is a particularly interest in the coexistence of different standards using close frequency bands. This notably involves designing the elements of the chain for receiving signals in a mobile terminal intended for transmitting other signals in close frequency bands. In practice, this may involve coexistence between the three aforementioned standards, DVB-H/T, LTE and GSM, as diagrammatically illustrated in FIG. 10. Due to the proximity of the concerned radio frequency bands and emission levels of the signals in question, such as +33 dBm for GSM signals, it is necessary that the multi-standard mobile terminal includes a radio frequency filtering device allowing reception of DVB-H/T signals not disturbed or degraded by GSM or LTE signals transmitted by the terminal, which must also be compact and inexpensive to produce, in order to meet the constraints of integration in mobile phones.

### PRIOR ART

We know from the patent application FR 2909239 filed on Nov. 27, 2006 the definition of a selective low-pass active filter for the reception of DVB-H/T signals in a mobile terminal which can also transmit signals in the RF band reserved for the cellular telephone (890-915 MHz), for example GSM signals. For the specified application, which is concerned with the relatively low frequency signals, typically less than 1 GHz, this filter can notably be produced from a low cost multilayer substrate and discrete components, typically carried SMD components, contributing to the compactness of the filter and its low cost.

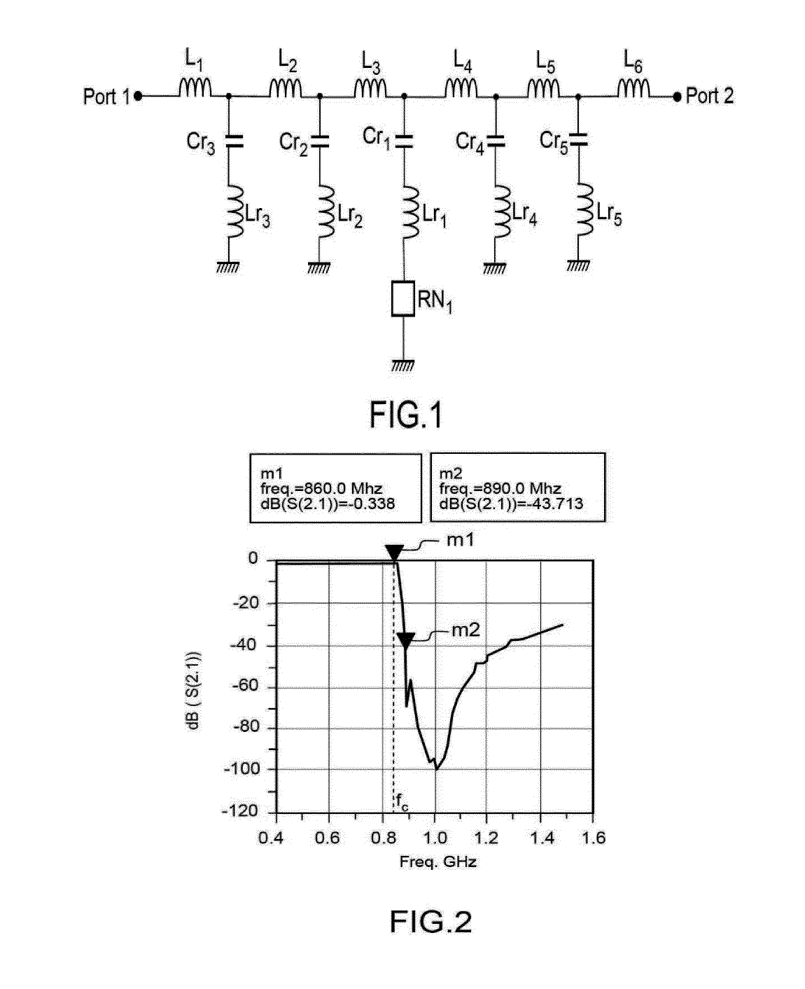

An embodiment of this filter is shown in FIG. 1, and its response is depicted in FIG. 2. The filter mainly comprises a transmission line between an input port 1 and an input port 2, consisting of a serial inductance network (L₁ to L₆), and LC resonators ((Lr₁, C₁), . . . (Lr₆, C₆)), with a resonator connected to each junction between two network inductances. It also includes one or more negative resistances in series with the LC resonators, to compensate for insertion losses inherent in passive components of the low-pass filter. These negative resistances are simulated by bipolar transistor(s) active circuits, hence the term active filter.

In the shown embodiment, the LC resonator at the centre (Lr₁, C₁) has the closest resonance frequency to the filter cut-off frequency and the filter comprises a negative resistance RN₁ in series with this resonator. The negative resistance is formed in practice by an active circuit of adapted topology bipolar transistor.

The values of the various components of the filter are chosen to obtain the desired low-pass filter template, with a band rejection at the level required for the application.

FIG. 2 illustrates a response curve dB (S (2,1)) (ratio of the power level of the received signal in output 2 to the power level of the signal sent in input 1) obtained by simulation. Point m1 on the curve corresponds to the filter cut-off frequency f_{c} equal to 860 MHz. Up to this frequency, the signal attenuation at the output of the filter corresponding to (low) insertion losses are −0.338 dB. Point m2 on the curve shows that the rejection at 890 MHz (beginning of the GSM band) is 43.71 dB. The obtained template which satisfactorily meets the specific requirements of the intended application is achieved in practice by means of a filter of order 11.

In this context, if we also want a third standard to coexist using a part of the band reserved for DVB-H/T, such as the LTE standard in the frequency plan currently used in the United States, this filter does not on its own meet the additional constraint of coexistence. It is necessary to consider an additional filter, placed in cascade before the low-pass filter, to reject this part of the band which is within the bandwidth of the low-pass filter.

Cascading the two filters is not favourable in terms of insertion losses and space. Constraints in terms of space are indeed very strong.

### SUMMARY OF THE INVENTION

THE invention provides a solution to allow the problems of coexistence of these different standards, by proposing an optimal filter structure in terms of response and space.

The invention proposes an active filter with dual response enabling the coexistence of at least three standards used to reject a first band by low-pass filtering, and a second band by rejection within the bandwidth of the low-pass filtering. In the context of the frequency plan currently used in the United States, the first band corresponds to the GSM standard, and the second band corresponds to the LTE standard.

We start with a low-pass active filter structure with cut-off frequency f_{c}, comprising a main conductor line between an input port and an output port of the device, consisting of an input conductor section, an output conductor section, and an inductance network in series between the input and output sections, the inductance network being coupled to the LC resonators, an LC resonator connected to each junction point between two network inductances and at least one negative resistance in series with one of the resonators. An auxiliary conductor line is coupled electro-magnetically to the main line, with one end of the auxiliary line on the input side of the filter connected to an electrical ground. The auxiliary line has a resonant frequency less than the cut-off frequency of the low-pass filter and forms by coupling with the low-pass filter, a stop-band or notch resonator: a radio frequency signal received at the input port of the filter, with a frequency corresponding to the resonant frequency of the auxiliary line, is absorbed by the notch resonator. Thus a band rejection within the bandwidth of the low-pass filter is obtained by coupling.

To limit space, the length of the auxiliary line is not greater than the length of the main line. To do this, an active capacitor is connected to the end of the auxiliary line on the output side, the value of which is adjusted to obtain the desired resonant frequency.

Preferably, to prevent input/output coupling via the auxiliary line, which tends to degrade the level of rejection outside the low-pass filter band, the auxiliary line extends, from the input end, a length less than that of the main line.

The invention concerns an active filter with dual response, made from a low-pass active filter structure and a multi-standard terminal implementing such a filter.

We can thus obtain a filter which has good performance even with the use of low-cost substrates in terms of both insertion losses in DVB-H/T band and LTE and GSM parasites bands rejection, and which remains compact, satisfying the integration and application constraints in mobile phones in particular.

Other characteristics and advantages of the invention are presented in the following detailed description with reference to the attached drawings in which:

FIG. 1, already described, is an electrical diagram of a low-pass active filter structure in accordance with the prior art, which can be used in a multi-standard mobile terminal intended for integrating digital television systems and cellular phones;

FIG. 2, already described, is a response curve for the corresponding transmission obtained by simulation of the structure shown in FIG. 1;

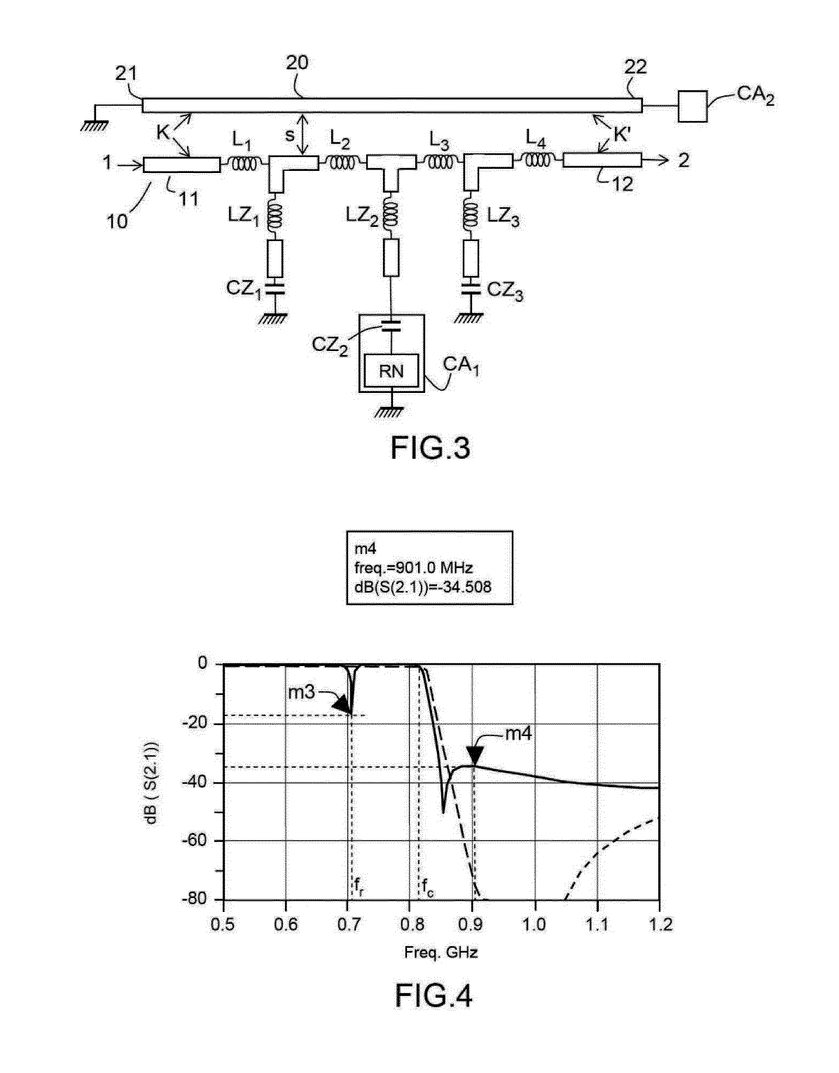

FIG. 3 diagrammatically shows an active filter structure with dual response, according to a first embodiment of the invention, and

FIG. 4 shows the response in corresponding transmission

FIG. 5 shows an active filter structure with dual response, according to a second embodiment of the invention, and

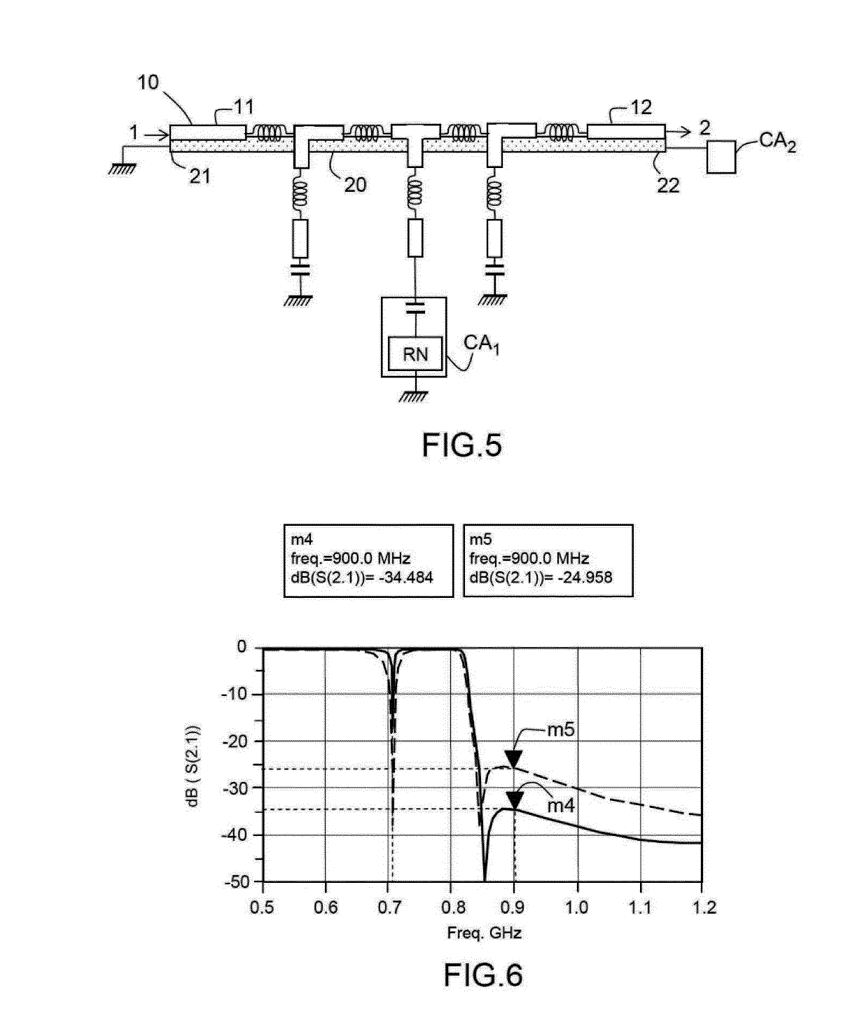

FIG. 6 shows corresponding response in transmission

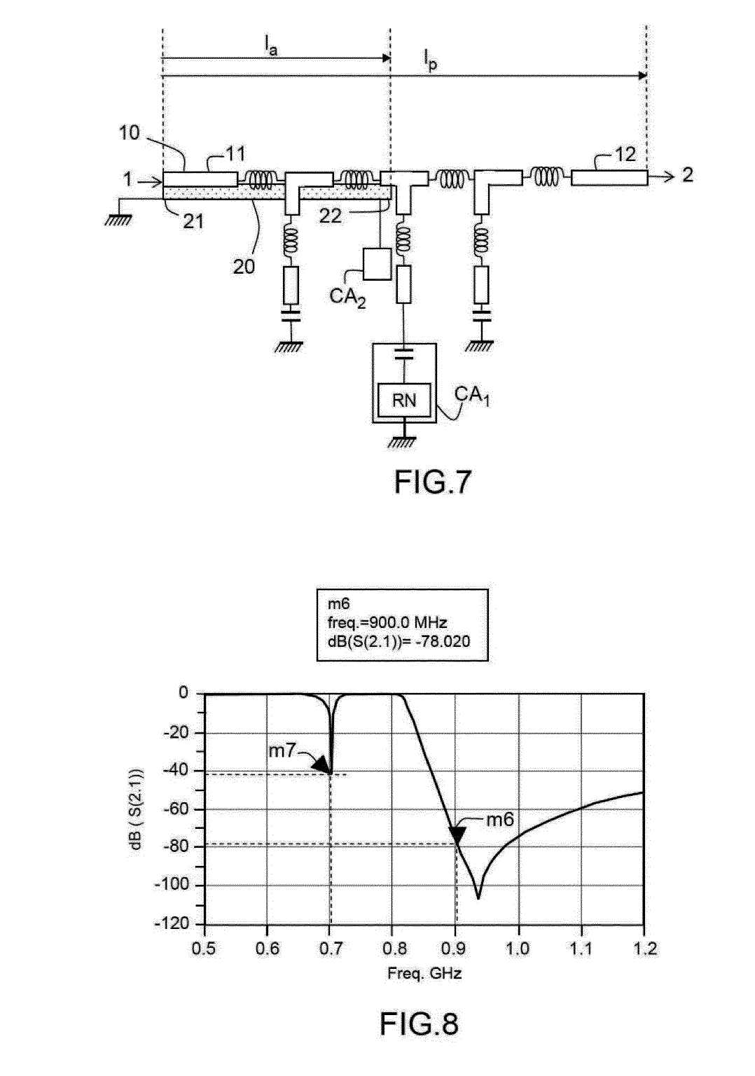

FIG. 7 shows an active filter structure with dual response, according to a third embodiment of the invention, and

FIG. 8 shows the corresponding response in transmission

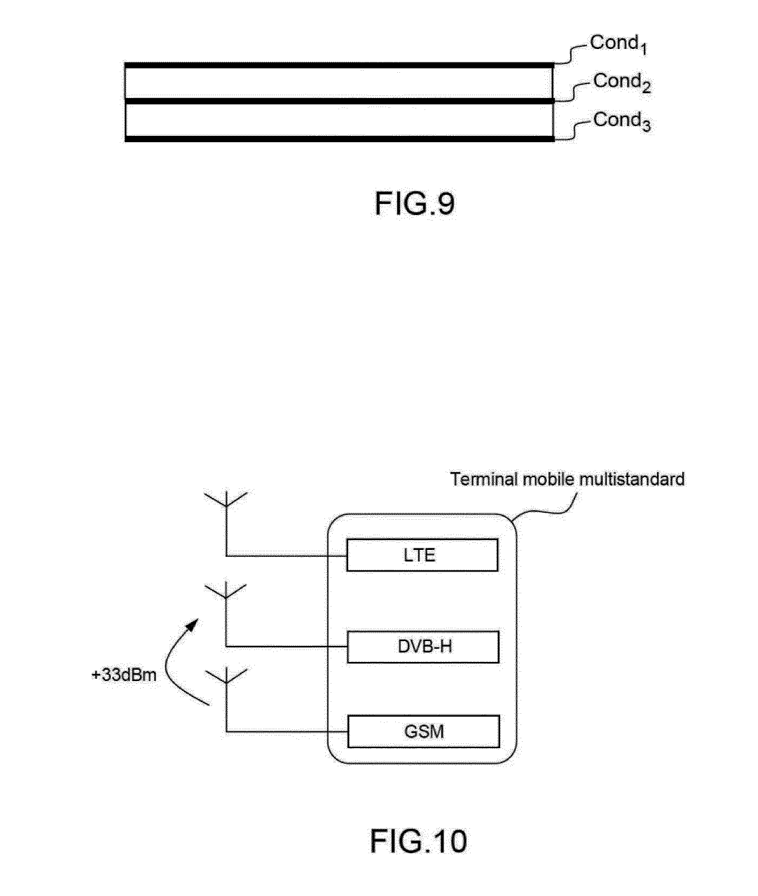

FIG. 9 is a sectional simplified view of a multilayer substrate which can be used for manufacturing a filter according to the invention; and

FIG. 10, already described, diagrammatically illustrates a multi-standard mobile terminal, highlighting the problems of coexistence due to the proximity of the frequency bands DVB-H/T, LTE and GSM.

### DETAILED DESCRIPTION

FIG. 3 illustrates an active filter structure with dual response according to a first embodiment according to the invention.

It comprises a low-pass active filter structure corresponding to that described in relation to FIG. 1, comprising, between an input port 1 and output port 2, a main conductor line 10 consisting of an input conductor section 11, an output conductor section 12, and an inductances network in series between the input and output sections. The inductances network is coupled to LC resonators, with an LC resonator connected to each junction point between two network inductances.

To simplify the figure, it is limited to representing a network of n=4 inductances in series, L₁, L₂, L₃, L₄, and 3 LC resonators each consisting of an inductance LZᵢ in series with a capacitor CZᵢ with i=1 to 3.

It is intended that one or more negative resistances be placed in series between the resonators. In the illustrated example, the structure comprises a single negative resistance which is formed by an active capacity CA₁. This active capacity forms capacity CZ₂ of the resonator LC placed at the centre of the network between the inductances L₂ and L₃, and provides a negative resistance RN in series with the resonator. Such active capacity will have for example a topology with bipolar transistors in common emitter configuration in accordance with the instructions in the publication by II-Soo Kim et al, “Analysis of a novel active capacitance using BJT Circuit and its Application to RF Bandpass filters” , in IEEE MTT-S International Microwave Symposium Digest, 2005, Vol. 4, pp 2207-2210.

The configuration of the low-pass filter illustrated in FIG. 3, with a single negative resistance in series with a central resonator, corresponds to a filter structure taught in the aforementioned patent application FR2909239, which offers interesting performance in terms of the selectivity and stability of this filter.

This invention is now explained with respect to this particular configuration of the low-pass filter and in a practical application example in the context previously explained, how to reject the two LTE and GSM parasites bands. The invention is however not limited to this particular configuration of the filter. Notably the low-pass filter may include several negative resistances, and/or active circuits simulating negative resistances could be provided in addition to the capacities of the resonators. The invention is not limited to this practical application, but it is applied more generally to the rejection of two bands by low-pass filtering for one and by rejection within the bandwidth of the low-pass filtering for the other. The filter elements are chosen to correspond to practical applications.

According to the invention, the active filter further comprises an auxiliary conductive line 20, where one end 21 in the filter input port side is connected to the electrical ground. The auxiliary line 20 is extended from the end 21 along and away from the main line 10. Both lines are thus electromagnetically coupled. The auxiliary line forms a resonator, where resonant frequency is a function of the characteristics of the auxiliary line, in particular its length. These characteristics are defined so that the resonant frequency of the resonator is below the cut-off frequency f_{c} of the low-pass filter. Under these conditions, a wave received at the main line input, whose frequency corresponds to the resonant frequency, will be completely absorbed by the resonator formed by the auxiliary line, thus causing a rejection around a narrowband corresponding to the rejection band of this resonator. The coupling of the auxiliary line, resonant, to the low-pass filter structure thus forms a cut-band or notch filter ensuring a rejection within the low-pass filter bandwidth.

In the example of practical application, wherein we attempt to reject the LTE band located within the bandwidth of the low-pass filter, the resonant frequency of the auxiliary line is adjusted to correspond the central frequency, typically 700 MHz, of this band used by the LTE standard.

In the embodiment illustrated in FIG. 3, the main line and the auxiliary line are coplanar, at a distance s from one another. FIG. 4 thus reports the rejection of both LTE and GSM parasite bands obtained with such a filter, the first within the bandwidth of the low-pass filter, corresponding to the band rejected from the resonator formed by the coupled auxiliary line to the main line, and the second corresponding to the rejection of the low-pass filter.

To respond to the space constraints, the length of the auxiliary line is not greater than the length of the main line and the end of the auxiliary line on the output side of the device is connected to a capacitor CA₂, to compensate for the reduction in length of the resonant auxiliary line in order to keep the desired resonant frequency, 700 MHz in the example. The capacitor CA₂ is advantageously an active capacitor, rather than a passive capacitor, the negative resistance presented by the active capacitor to compensate for the overall losses of the resonant line, which improves the quality factor, and therefore, the resonator rejection level. It has been verified that these improvements provided by the active capacitor were not made at the expense of the noise degradation factor, compared to an identical structure using a passive capacitor.

This filter structure can be further improved. Indeed, as shown in FIG. 4 by the point m3, the rejection band centred around 710 MHz is narrow and the rejection is low, not exceeding 18 dB.

We also see that the low-pass filter rejection is degraded compared to that of the low-pass filter alone whose response is illustrated in FIG. 2. The point m4 thus indicates an attenuation around 34 dB at 900 MHz.

To improve the width of the rejection band of the notch resonator and its rejection level, it is necessary to increase the coupling between the auxiliary line and the main line, that is to say decrease the distance which separates them. In practice there is little room for manoeuvre because the design rules imposed by the industry stipulate the spacing cannot be less than 0.15 mm.

Another embodiment is thus suggested, in which the two lines are formed on the conductor planes separated by a dielectric substrate. Such filter structure may typically be achieved with a multilayer substrate as featured in FIG. 9, comprising two layers of dielectric substrate and three metal layers. Typically the main line and the LC resonators are formed on the upper metal layer Cond₁, and the auxiliary line on the intermediate metal layer Cond₂. The last layer Cond₃ is used to form an electrical ground plane.

What matters most in coupling is the width of the lines that are opposite each other and not the width of the lines themselves. Thus, this configuration allows you to adjust the width of the lines opposite one another to obtain the optimal coupling, without technological constraint (instead of a coplanar configuration).

A corresponding embodiment is diagrammatically illustrated in FIG. 5. To represent the position of the auxiliary line 20 in another conductor plane under the main line 10, it is represented with dashes and to a larger scale so that it protrudes from the main line. In reality, the widths of the two lines correspond approximately.

FIG. 6 shows with dotted lines, the response obtained with this configuration and with a solid line, the one shown in FIG. 4 corresponding to the configuration of the filter in FIG. 3, with coplanar lines, all other things being equal. It clearly demonstrates an improvement in the width of the resonator rejection band and its rejection level, close to 25 dB. On the other hand, the low-pass filter rejection is further degraded, with an attenuation of only 25 dB at 900 MHz (point m5) compared to 34 dB obtained with the configuration of FIG. 3 (point m4).

This degradation of the low-pass filter rejection is mainly due to a coupling between the input section and the output section, by the resonant auxiliary line. If we detail the coupling between the two lines, a first coefficient K of coupling can be assigned between the auxiliary line and the input section, and a second coefficient K′ of coupling between the auxiliary line and the outlet section. The auxiliary line is also coupled to the small conductive sections of the main line connecting the network inductances, L₁, L₂, . . .

An improvement consists of reducing the length of the auxiliary line to prevent coupling between this line and the outlet section of the main line. The reduction of the auxiliary line length is then compensated by the value of the active capacitor to maintain the selected resonant frequency. This improvement can be combined with the two configurations in FIGS. 3 and 5.

FIG. 7 illustrates a corresponding configuration, applied to the configuration in FIG. 5 with superimposed auxiliary and main lines. The auxiliary line extends, from its filter input port end, along the main line, a length lₐ which is shorter than the lₚ length of the main line. This lₐ length is advantageously chosen so that the auxiliary line does not extend the length of the main line output section. With respect to FIG. 3 the filter input/output coupling is thus minimised: the low-pass filter rejection is then greatly improved.

The combination of superimposed lines in two different conductor planes and the reduction of the length of the auxiliary line produce an efficient dual response filter. The results of the simulation of such a filter are illustrated in FIG. 8 and show a rejection of both parasite bands, with an attenuation in the rejection band of the low-pass filter which exceeds 70 dB (point m6), and an attenuation of over 40 dB in the rejection band of the resonator within the bandwidth of the low-pass filter (point m7).

It can be noticed that the insertion losses in the low-pass filter bandwidth are low.

The invention has been described in connection with a particular application, wherein the operating frequency is less than 1 GHz. In this context, different filter elements, notably the inductances and capacitors, are discrete elements, such as SMD components, which contribute to filter compactness, but distributed technologies could be used for applications addressing higher frequencies.

1. Active filter with dual response, comprising a main conductive line between an input port and an output port, including an input conductive section, an output conductive section, and an inductance network in series between the input and output conductive sections, the inductance network being coupled to the LC resonators, an LC resonator connected to each junction point between two network inductances, and at least one negative resistance in series with one of the resonators, the main line, the LC resonators and the negative resistances forming an active low-pass filter with a cut-off frequency f_{c}, wherein the filter comprises a conductive auxiliary line, having one end at the filter input side is connected to an electrical ground, and forming a resonator with a resonant frequency fᵣ less than the cut-off frequency f_{c} of the low-pass filter, the auxiliary line extending from said end, along and being away from the main line, and forming by coupling a rejection filter around the said resonant frequency in the low-pass filter bandwidth.

2. Filter according to claim 1, wherein the length of the line is not greater than the length of the main line and the end of the auxiliary line in the output side of the device is connected to an active capacitor whose the value is adjusted to obtain the desired resonant frequency.

3. Filter according to claim 2, in wherein the auxiliary line extends from the input side end at least along the input section of the main line, a length less than that the length of the main line.

4. Filter according to claim 1, wherein the main line and the auxiliary line are formed on conductive layers different from a multilayer substrate.

5. Filter according to claim 1, wherein the main line and the auxiliary line are coplanar.

6. Multi-standard terminal comprising at least one filter according to claim 1.

7. An active filter with dual response comprising:
a low-pass active filter structure with a cut-off frequency and comprising a main conductive line between an input port and an output port; and
a conductive auxiliary line forming a resonator with a resonant frequency less than the cut-off frequency of the low-pass filter, the auxiliary line extending from said end, along and being away from the main line, and forming by coupling a rejection filter around the said resonant frequency in the low-pass filter bandwidth.

8. Multi-standard terminal comprising at least one filter according to claim 7.
